(19) United States
(12) Patent Application Publication
(10) Pub. No.: US 2020/0027962 A1
(43) Pub. Date: Jan. 23, 2020

(54) SEMICONDUCTOR DEVICE AND METHOD FOR MANUFACTURING SEMICONDUCTOR DEVICE

(71) Applicant: KABUSHIKI KAISHA TOSHIBA, Tokyo (JP)

(72) Inventors: Masafumi HAMAGUCHI, Ota Tokyo (JP); Shinji KAWAHARA, Yokohama Kanagawa (JP)

(21) Appl. No.: 16/587,764

(22) Filed: Sep. 30, 2019

Related U.S. Application Data
(62) Division of application No. 15/372,190, filed on Dec. 7, 2016.
(60) Provisional application No. 62/304,730, filed on Mar. 7, 2016.

(51) Int. Cl. H01L 29/51; H01L 27/11521

(52) U.S. Cl. CPC H01L 29/517; H01L 27/11246; H01L 27/11521

(57) ABSTRACT

According to one embodiment, a semiconductor device includes a memory cell array including a first memory cell provided on a substrate and a second memory cell provided on the substrate. The memory cell array includes a charge storage layer provided on the substrate and a control electrode provided on the charge storage layer. A coupling ratio of the second memory cell is different from a coupling ratio of the first memory cell.

### CROSS-REFERENCE TO RELATED APPLICATION

This application is a division of U.S. patent application Ser. No. 15/372,190, filed on Dec. 7, 2016, which is based upon and claims the benefit of priority from U.S. Provisional Patent Application 62/304,730, filed on Mar. 7, 2016, the entire contents of each of which are incorporated herein by reference.

### FIELD

Embodiments described herein relate generally to a semiconductor device and a method for manufacturing a semiconductor device.

### BACKGROUND

In a memory cell transistor (hereinafter referred to as a memory cell) including a control gate electrode and a charge storage layer such as a floating gate electrode, a coupling ratio (CR) between the control gate electrode and the floating gate electrode is one of parameters characterizing a performance of a memory cell.

### BRIEF DESCRIPTION OF THE DRAWINGS

FIG. 1 is a schematic plan view exemplifying a planar layout of a major element in a semiconductor memory device of an embodiment;

FIG. 2A is a schematic cross-sectional view corresponding to A-A′ section in FIG. 1, and FIG. 2B is a schematic cross-sectional view corresponding to B-B′ section in FIG. 1;

FIG. 3 is a schematic plan view of an arrangement example of a memory cell of the semiconductor memory device of the embodiment;

FIGS. 4A to 6B are schematic cross-sectional views showing a method for manufacturing the semiconductor memory device of the embodiment;

FIG. 7 is a schematic view explaining a mask used in the embodiment;

FIGS. 8A and 8B are schematic cross-sectional views showing a method for manufacturing the semiconductor memory device of the embodiment;

FIGS. 9A and 9B are schematic cross-sectional views showing a method for manufacturing a first example of the semiconductor memory device of the embodiment;

FIGS. 10A and 10B are schematic views explaining another example of the mask of the embodiment;

FIG. 11 is a schematic plan view of a second example of the semiconductor memory device of the embodiment;

FIG. 12 is a schematic plan view of a third example of the semiconductor memory device of the embodiment; and

FIG. 13 is a block diagram of a fourth example of a semiconductor device of the embodiment.

### DETAILED DESCRIPTION

According to one embodiment, a semiconductor device includes a memory cell array including a first memory cell provided on a substrate and a second memory cell provided on the substrate. The memory cell array includes a charge storage layer provided on the substrate and a control electrode provided on the charge storage layer. A coupling ratio of the second memory cell is different from a coupling ratio of the first memory cell.

Embodiments will now be described with reference to the drawings. The same components in the drawings are marked with the same reference numerals. Although silicon is exemplified in the following embodiments as a semiconductor, a semiconductor other than silicon may be used.

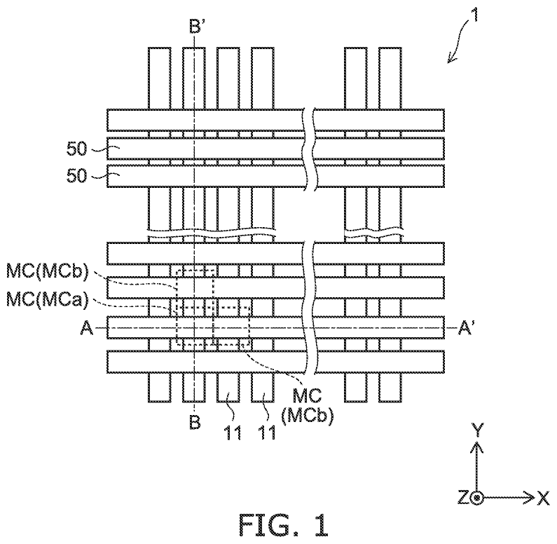

FIG. 1 is a schematic plan view of a semiconductor memory device of an embodiment.

The semiconductor memory device of the embodiment includes a memory cell array 1. The memory cell array 1 includes a plurality of semiconductor regions (active regions) 11 and a plurality of control gate electrodes 50. A planar layout of the semiconductor regions 11 and the control gate electrodes 50 is shown in FIG. 1.

The semiconductor regions 11 extend in a Y-direction (first direction). The semiconductor regions 11 are separate from each other in a X-direction intersecting with the Y-direction. For example, the X-direction is substantively perpendicular to the Y-direction. The control gate electrodes 50 extend in the X-direction (second direction) different from the Y-direction. The control gate electrodes 50 are separate from each other in the Y-direction intersecting with the Y-direction. For example, the Y-direction is substantively perpendicular to the X-direction. The control gate electrodes 50 extend across the semiconductor regions 11 in the X-direction above the semiconductor regions 11.

A memory cell MC described below is provided at an intersection of the semiconductor region 11 and the control gate electrode 50. The memory cell array 1 includes a plurality of memory cells MC arrayed in the X-direction and the Y-direction.

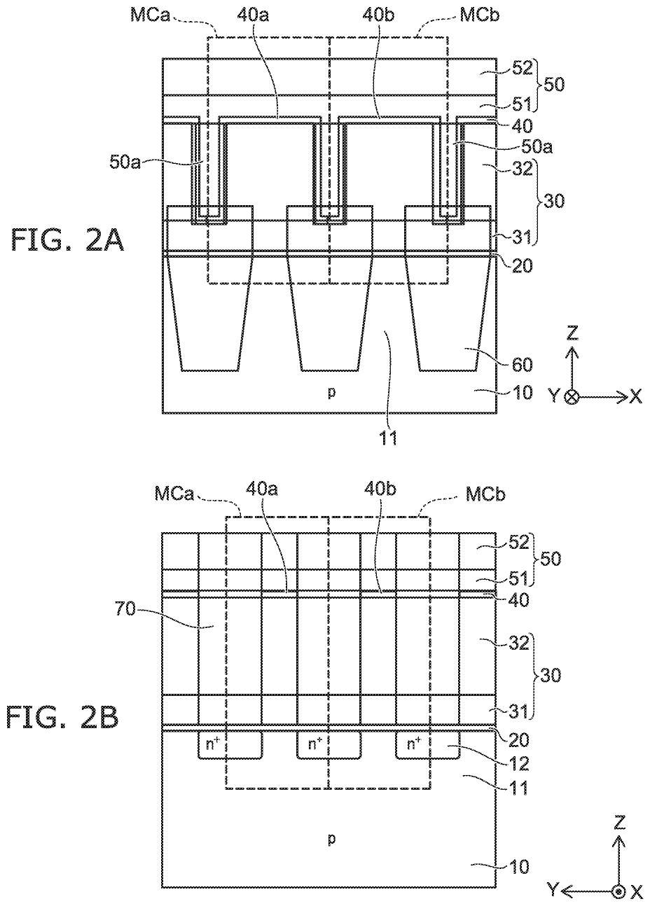

FIGS. 2A and 2B are schematic cross-sectional views of the semiconductor memory device of the embodiment. FIG. 2A is a schematic cross-sectional view corresponding to a part of A-A′ section in FIG. 1. FIG. 2B is a schematic cross-sectional view corresponding to a part of B-B′ section in FIG. 1. In FIGS. 2A and 2B, the positive direction of the Z-axis is upward, and the negative direction of the Z-axis is downward.

As shown in FIG. 2A, the fin-like semiconductor regions (active regions) 11 extending in the Y-direction are formed on a major surface side of the substrate 10. The semiconductor regions 11 are separated in the X-direction by separation portions 60 having shallow trench isolation (STI) structure.

As shown in FIG. 2B, n⁺-type semiconductor regions (source/drain regions) 12 are provided in a surface of the semiconductor region 11. The semiconductor regions 12 are separated each other and arrayed in the Y-direction. A p-type region (channel region) is formed between the n⁺-type semiconductor regions 12 in the semiconductor region 11.

A first insulating film (gate insulating film, tunneling insulating film) 20 is provided on the semiconductor region 11. The first insulating film 20 is, for example, a silicon oxide film. As shown in FIG. 2A, the first insulating film 20 is divided into a plurality in the X-direction by the separation portions 60. As shown in FIG. 2B, the first insulating film 20 continuously extends in the Y-direction.

A plurality of charge storage layers 30 is provided on the first insulating film 20. The charge storage layer 30 is a polysilicon film doped with, for example, phosphorus that is a dopant for a conductive polysilicon. The charge storage layer 30 may be a silicon film doped with phosphorus and carbon. The charge storage layer 30 may contain tungsten, titanium nitride, or tantalum nitride. As shown in FIGS. 2A and 2B, the charge storage layers 30 are divided in the X-direction and the Y-direction. As shown in FIG. 2B, the charge storage layers 30 are divided in the Y-direction by insulating films 70. As shown in FIG. 2A, a portion 50a of the control gate electrode 50 is provided between the adjacent charge storage layers 30 in the X-direction. A second insulating film 40 is provided between the portion 50a of the control gate electrode 50 and the charge storage layers 30. The charge storage layer 30 is a floating gate electrode.

The second insulating film (interelectrode insulating film) 40 is provided on the charge storage layer 30. The second insulating film 40 is formed of a material having a dielectric constant higher than a dielectric constant of the first insulating film 20. The second insulating film 40 is provided on the upper surface of the charge storage layers 30. As shown in FIG. 2A, the second insulating film 40 is provided also on the side surface in the X-direction of the charge storage layers 30. The second insulating film 40 is continuous in the X-direction along the side surface and the upper surface of the charge storage layers 30. As shown in FIG. 2B, the second insulating film 40 is divided into a plurality in the Y-direction by the insulating films 70. The material of the second insulating film 40 is described below.

The control gate electrode 50 is provided on the second insulating film 40. The control gate electrode 50 can be formed of the same material as the charge storage layer 30 that is the floating gate electrode. As shown in FIG. 1 and FIG. 2A, the control gate electrode 50 extends in the X-direction. As shown in FIG. 1 and FIG. 2B, the control gate electrode 50 is divided into a plurality in the Y-direction by the insulating films 70. The control gate electrode 50 can be referred to as a word line.

As shown in FIG. 2A, the semiconductor region 11, the first insulating film 20, and a lower portion of the charge storage layers 30 are separated in the X-direction by the separation portions 60 having STI structure. A trench is formed between the above elements that are adjacent in the X-direction. The insulating film is buried in the trench.

As shown in FIG. 2B, the charge storage layers 30, the second insulating film 40, and the control gate electrodes 50 are separated in the Y-direction by the interlayer insulating film (dielectric film) 70.

The charge storage layer 30 is surrounded by the insulator, and is not electrically connected to anywhere. The electron stored in the charge storage layer 30 is not released from the charge storage layer 30 and the electron is not injected into the charge storage layer 30 even when the power supply is OFF. The semiconductor memory device (semiconductor device) of the embodiment is a nonvolatile semiconductor memory device that can retain the data without the power supply.

The charge storage layer 30 may have many trap sites that trap charge inside an insulative film. Such a charge storage layer 30 may include a silicon nitride film.

The control gate electrode 50 is provided on the upper surface of the charge storage layer 30 with the second insulating film 40 interposed. As shown in FIG. 2A, the portion 50a of the control gate electrode 50 is provided between the adjacent charge storage layer 30 in the X-direction. The second insulating film 40 is provided between the portion 50a of the control gate electrode 50 and the side surface of the charge storage layer 30.

The control gate electrode 50 faces to the upper surface and the side surface of the charge storage layer 30 with the second insulating film 40 interposed. The control gate electrode 50 faces to the upper surface of the charge storage layer 30, and faces to also the side surface of the charge storage layer 30. This increase an opposing area of the control gate electrode 50 and the charge storage layer 30, and increase a capacitance between the control gate electrode 50 and the charge storage layer 30. The strong capacitance coupling between the control gate electrode 50 and the charge storage layer 30 enhances the write efficiency and the erase efficiency.

As shown in FIG. 1, the memory cell MC is arrayed at the intersection of the control gate electrode 50 and the semiconductor region 11. The memory cell MC includes the semiconductor region 11, the first insulating film 20, the charge storage layer 30, the second insulating film 40, and the control gate electrode 50. One memory cell MC includes one charge storage layer 30 that is provided at the intersection of the control gate electrode 50 and the semiconductor region 11, and provided between the control gate electrode 50 and the semiconductor region 11. In the example shown in FIG. 1, the plurality of memory cells MC are arrayed in a matrix in the X-direction and the Y-direction parallel to the major surface of the substrate 10.

The memory cell array 1 of the embodiment includes, as shown in FIGS. 1, 2A and 2B, a first memory cell MCa and a second memory cell MCb. Each of the first memory cell MCa and the second memory cell MCb includes the semiconductor region 11, the first insulating film 20, the charge storage layer 30, the second insulating film 40, and the control gate electrode 50 as referred to above. In the following description, the elements of the first memory cell MCa and the second memory cell MCb may be distinguished by reference numerals and signs. The reference sign “a” is added to the reference numeral or sign of the element of the first memory cell MCa. The reference sign “b” is added to the reference numeral or sign of the element of the second memory cell MCb.

According to the embodiment, a coupling ratio (first coupling ratio) of the first memory cell MCa is different from a coupling ratio (second coupling ratio) of the second memory cell MCb.

The coupling ratio CR is represented by the first capacitance Cₜₙₗ between the semiconductor region 11 and the charge storage layer 30, and the second capacitance C_{ipd} between the charge storage layer 30 and the control gate electrode 50. For example, the coupling ratio CR is the ratio of the second capacitance C_{ipd} to the capacitance (Cₜₙₗ+C_{ipd}) viewed from the charge storage layer 30. The coupling ratio CR is calculated by the following equation (1).

CR=C_{ipd}/(Cₜₙₗ+C_{ipd}) (1)

In the embodiment, the coupling ratio of the first memory cell MCa is different from the coupling ratio of the second memory cell MCb by changing the dielectric constant of the material of the second insulating film 40a of the first memory cell MCa and the dielectric constant of the material of the second insulating film 40b of the second memory cell MCb. For example, the material of the second insulating film 40b of the second memory cell MCb contains a major element different from a major element contained in the material of the second insulating film 40a of the first memory cell MCa.

For example, the high-k material such as hafnium oxide (HfO₂) is used as the second insulating film 40a of the first memory cell MCa. The second insulating film 40a may be, for example, a silicon nitride film, or an insulating film containing hafnium aluminate.

When the material of the second insulating film 40a of the first memory cell MCa is hafnium oxide, for example, hafnium silicate (HfSiO), or hafnium oxide doped with silicon is used as the material of the second insulating film 40b of the second memory cell MCb.

When the material of the second insulating film 40a of the first memory cell MCa is silicon oxynitride, for example, aluminum silicate containing nitrogen, or silicon oxynitride doped with aluminum is used as the material of the second insulating film 40b of the second memory cell MCb.

When the material of the second insulating film 40a of the first memory cell MCa is an insulating film containing hafnium aluminate, for example, an insulating film containing hafnium aluminate having an aluminum concentration higher than an aluminum concentration in the second insulating film 40a of the first memory cell MCa is used as the material of the second insulating film 40b of the second memory cell MCb.

The second insulating film 40a of the first memory cell MCa is not limited to the above example. The insulating material having changeable dielectric constant by doping an element not contained in the second insulating film 40a or an element not major element of the second insulating film 40a is used as the material of the second insulating film 40a.

The material having the changed dielectric constant is used as the material of the second insulating film 40b of the second memory cell MCb.

The change of the dielectric constant of the second insulating film 40 between the charge storage layer 30 and the control gate electrode 50 changes the second capacitance C_{ipd} between the charge storage layer 30 and the control gate electrode 50. According to the above equation (1), the coupling ratio CR of the first memory cell MCa can be different from the coupling ratio CR of the second memory cell MCb.

According to the embodiment, the first memory cell MCa and the second memory cell MCb having the coupling ratio CR different from the coupling ratio CR of the first memory cell MCa are formed on the same substrate 10. The first memory cell MCa and the second memory cell MCb having the coupling ratio CR different from the coupling ratio CR of the first memory cell MCa are included in one chip.

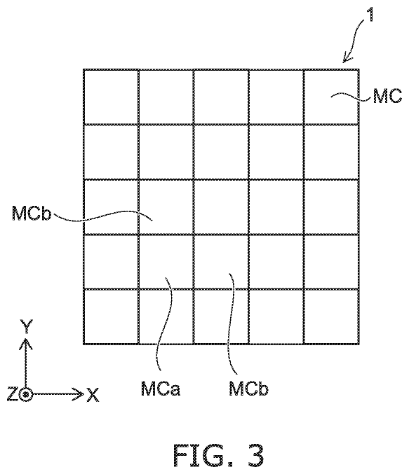

The number of the first memory cell MCa and the second memory cell MCb, the arrangement of the first memory cell MCa and the second memory cell MCb on the substrate 10 are arbitrarily configured. FIG. 3 shows one example of the arrangement of the first memory cell MCa and the second memory cell MCb. In FIG. 3, the first memory cell MCa and the second memory cell MCb are alternately arranged in the X-direction, and the first memory cell MCa and the second memory cell MCb are alternately arranged in the Y-direction. FIG. 3 is a schematic view of the memory cell array 1 of the embodiment viewed from the X-direction or directly above.

The coupling ratio CR defines the voltage Vfg applied to the charge storage layer 30 by the control gate electrode 50 to which the voltage Vcg is applied. The higher coupling ratio CR increases the write efficiency and the erase efficiency of the data to the memory cell MC. The coupling ratio CR is one of the parameters characterizing the performance of the memory cell MC. According to the embodiment, the memory cell MCa and the memory cell MCb having different characteristics each other are provided on one substrate 10 or in one chip.

Next, a method for manufacturing the semiconductor memory device of the embodiment will now be described.

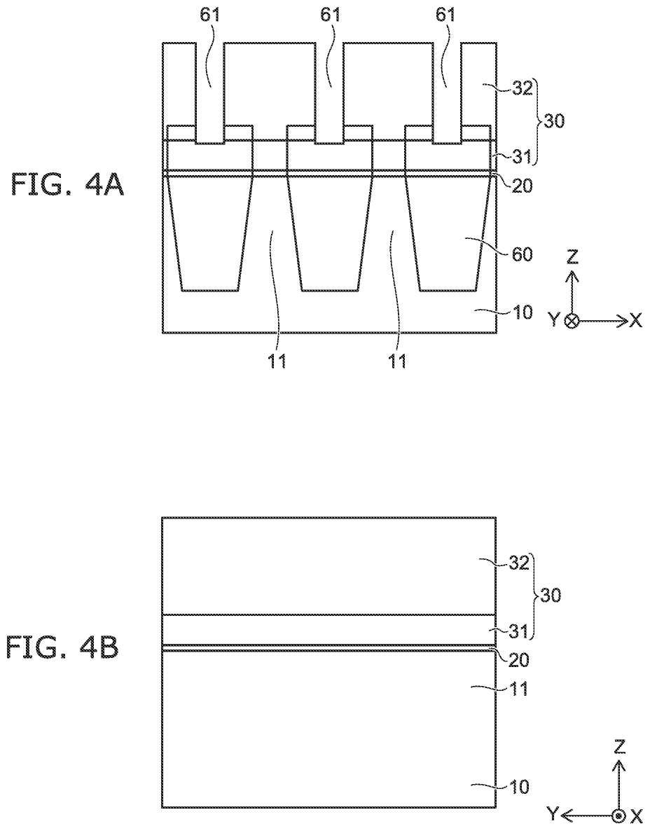

FIGS. 4A to 6B, and 8A to 9B are schematic views showing a method for manufacturing the semiconductor memory device of the embodiment. In these figures, FIG. A corresponds to a part of A-A′ section in FIG. 1, and FIG. B corresponds to a part of B-B′ section in FIG. 1.

FIGS. 4A and 4B show a state in which the first insulating film 20, the charge storage layer 30, and the separation portion 60 are formed on the substrate 10.

First, the first insulating film 20 is formed on the substrate 10. And then a first polysilicon film 31 is formed on the insulating film 20.

The first polysilicon film 31 and the insulating film 20 are etched in series by RIE method using a mask not shown. The first polysilicon film 31 and the insulating film 20 are divided in the X-direction. And then the exposed region of the substrate 10 is etched to form a trench. The fin-shaped semiconductor region 11 is formed between the adjacent the trenches in the X-direction.

The insulating film, for example, the silicon oxide film is buried in the trench and the separation portion 60 is formed.

The second polysilicon film 32 is deposited on the first polysilicon film 31 and the separation portion 60. The first polysilicon film 31 and the second polysilicon film 32 are included in the charge storage layer 30.

And then the second polysilicon film 32 on the separation portion 60 is selectively removed, for example, by RIE method using a mask not shown. The plurality of second polysilicon films 32 are separated in the X-direction with the trench 61 interposed between the second polysilicon films 32.

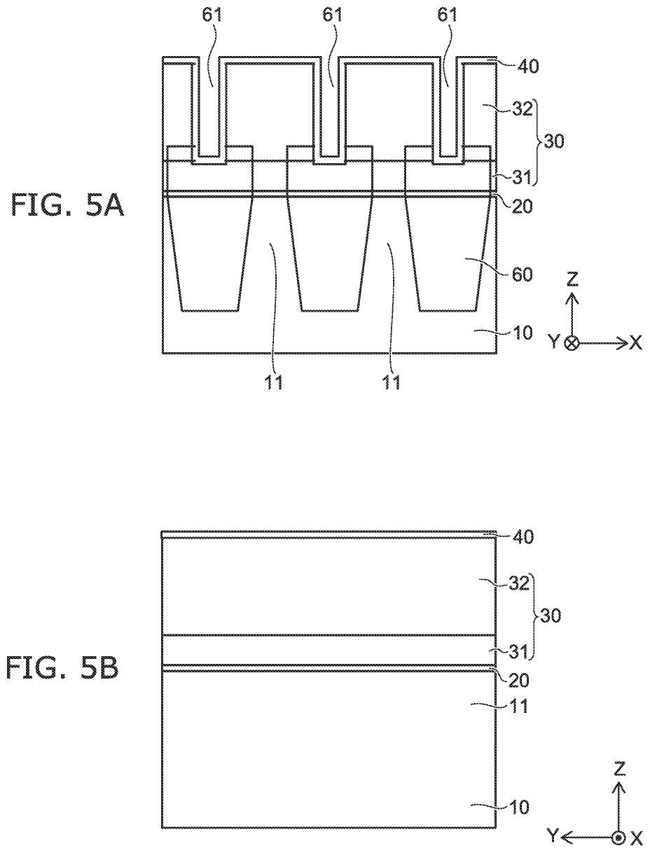

Next, as shown in FIGS. 5A and 5B, the second insulating film 40 is formed on the second polysilicon film 32. The second insulating film 40 is formed also on the side surface exposed in the trench 61 of the second polysilicon film 32. The second insulating film 40 is formed conformally along the side surface and the upper surface of the second polysilicon film 32.

For example, the hafnium oxide (HfO₂) film is formed as the second insulating film 40 by atomic layer deposition (ALD) method.

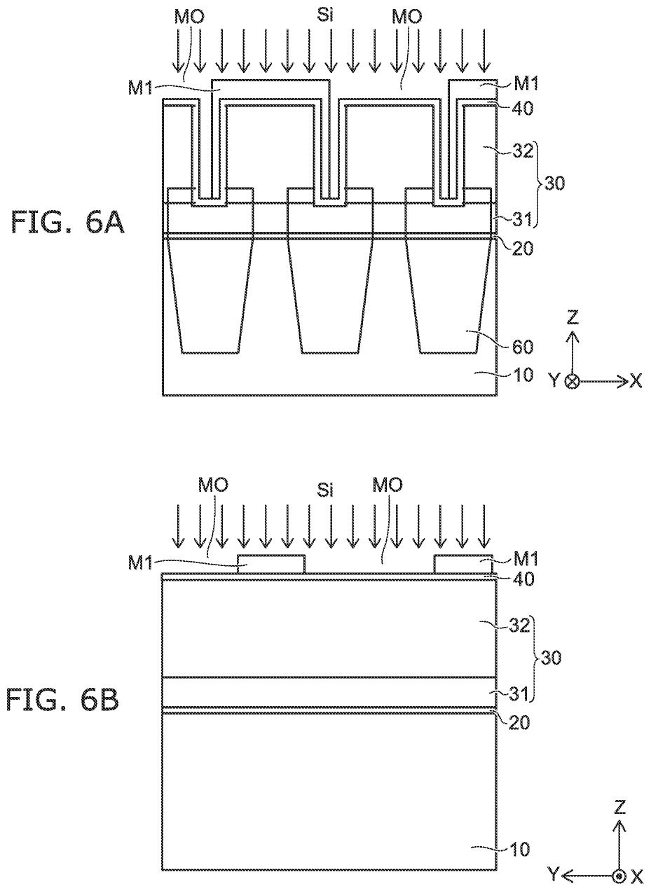

After depositing the second insulating film 40, the dielectric constant of the area of the part of the second insulating film 40 is changed. Here, the dielectric constant of the second insulating film 40 in the area corresponding to the second memory cell MCb is changed. According to the embodiment, the dielectric constant of the second insulating film 40 of the second memory cell MCb is changed by implanting silicon (si) selectively into the second insulating film 40 of the second memory cell MCb. The silicon is implanted by ion implantation method. As shown in FIGS. 6A and 6B, the area in which the silicon is not implanted, that is, the first memory cell MCa is covered with the mask M1.

After depositing the material film of the mask M1 on the second insulating film 40, the predetermined opening pattern is formed in the material film. The mask M1 is, for example, a resist film itself, or a film patterned using a resist film. Here, the opening portion MO is formed in the area corresponding to the second memory cell MCb.

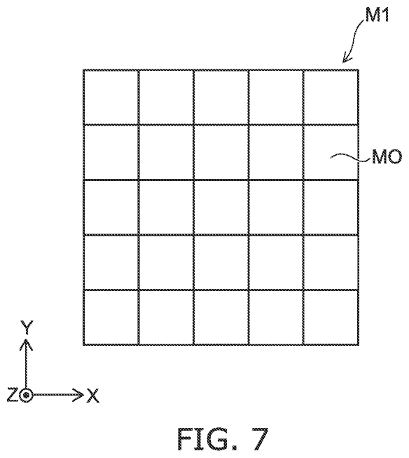

FIG. 7 shows the example of the opening pattern of the mask M1 used forming the memory cell array 1 shown in FIG. 3. The memory cell MCa having high coupling ratio CR, and the memory cell MCb having low coupling ratio CR are alternately arranged in the memory cell array 1. As shown in FIG. 7, the opening portion MO of the mask M1 is formed in the area corresponding to the memory cell MCb having low coupling ratio CR.

The silicon is implanted into the second insulating film 40 exposed in the opening portion MO by ion implantation method. The dose amount of the silicon is, for example, 1×10¹⁴ to 1×10¹⁶ atom/cm².

The silicon is not implanted into the second insulating film 40 of the area covered with the mask M1. The second insulating film 40 of the area doped with the silicon becomes a hafnium silicate film. The dielectric constant of the hafnium silicate film is lower than the dielectric constant of the second insulating film 40 (hafnium oxide film) of the area not doped with the silicon. Or, the second insulating film 40 of the area doped with the silicon contains silicon at a higher concentration than the second insulating film 40 of the area not doped with the silicon, and have a dielectric constant lower than that of the second insulating film 40 of the area not doped with the silicon. After implanting the silicon, the mask M1 is removed.

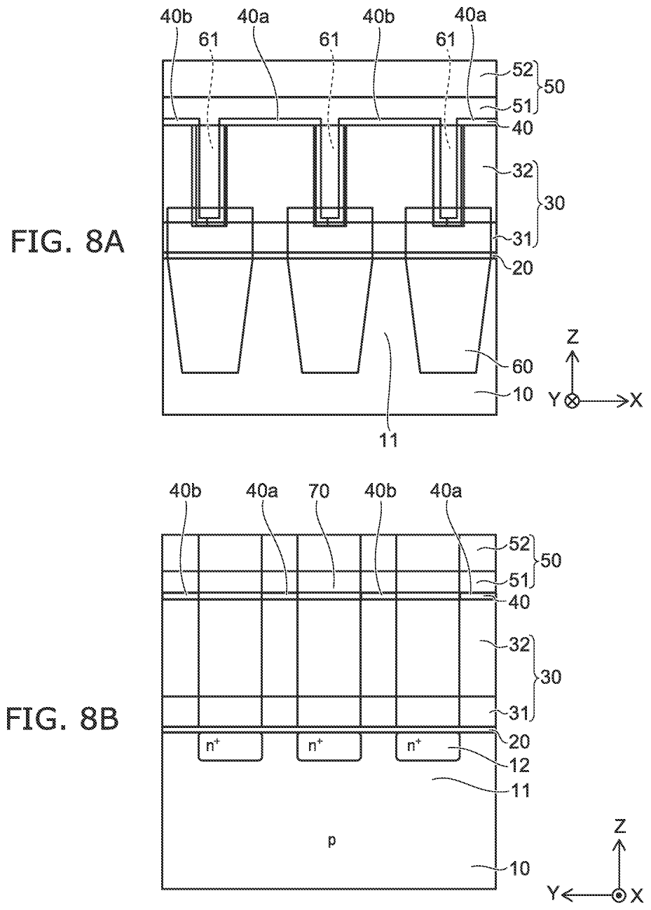

After removing the mask M1, as shown in FIGS. 8A and 8B, the control gate electrode 50 is formed on the second insulating film 40.

First, a polysilicon film 51 is formed. As shown in FIG. 8A, a portion of the polysilicon film 51 is formed also in the trench 61 between the adjacent second polysilicon films 32 in the X-direction. A metal silicide film 52 is formed on the polysilicon film 51. The polysilicon film 51 and the metal silicide film 52 are included in the control gate electrode 50.

As shown in FIG. 8B, the control gate electrode 50, the second insulating film 40, and the charge storage layer 30 are selectively etched to expose the first insulating film 20, and a plurality of cell separating trenches extending in the X-direction are formed. The control gate electrode 50, the second insulating film 40, and the charge storage layer 30 are divided into plural parts in the Y-direction by the cell separating trenches.

Next, an n-type impurity ion is implanted into the surface of the semiconductor region 11 through the gate insulating film 20 exposed in the cell separating trench. The n-type impurity ion implanted into the surface of the semiconductor region 11 is, for example, arsenic ion or phosphorus ion. The interlayer insulating film 70 is formed in the cell separating trench by plasma CVD method. And then a contact (not shown) connected to the semiconductor region 12 is formed in the interlayer insulating film 70.

In the above embodiment, after forming the second insulating film 40, before forming the control gate electrode 50, the ion is selectively implanted into the second insulating film 40. However, the method for manufacturing the semiconductor memory device of the embodiment is not limited to the above method. For example, after forming the polysilicon film 51 of the control gate electrode 50, before forming the metal silicide film 52, the silicon ion may be implanted into the second insulating film 40 through the polysilicon film 51.

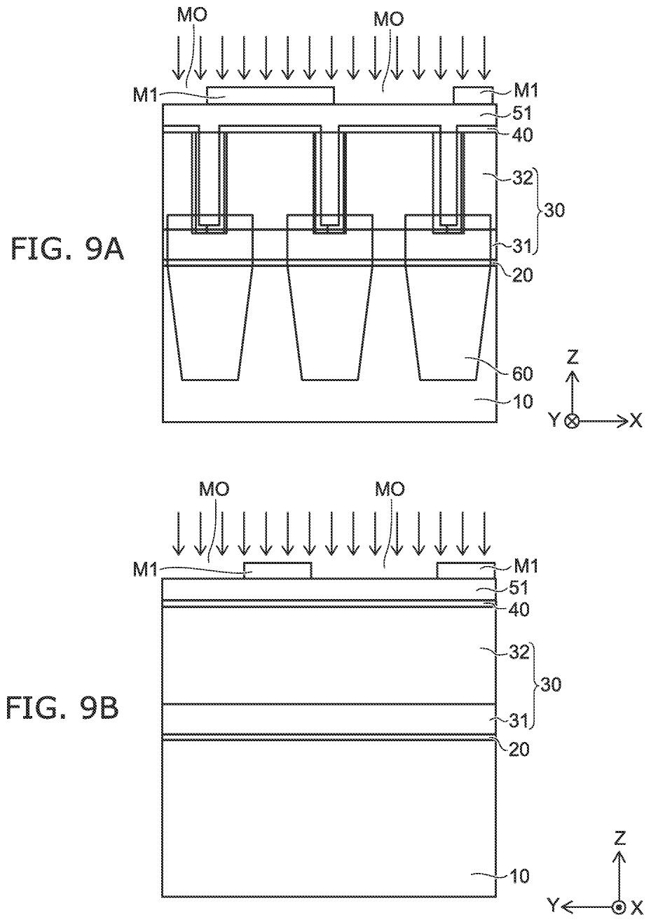

Also in this instance, as shown in FIGS. 9A and 9B, the ion is selectively implanted with covering the region where the ion is not implanted with the mask M1. The ion, which has higher energy than energy for the case of ion implantation before forming the polysilicon film 51, penetrates through the polysilicon film 51 and is implanted into the second insulating film 40.

The memory cell array 1 including the plurality of memory cells MC may have three or more different coupling ratios.

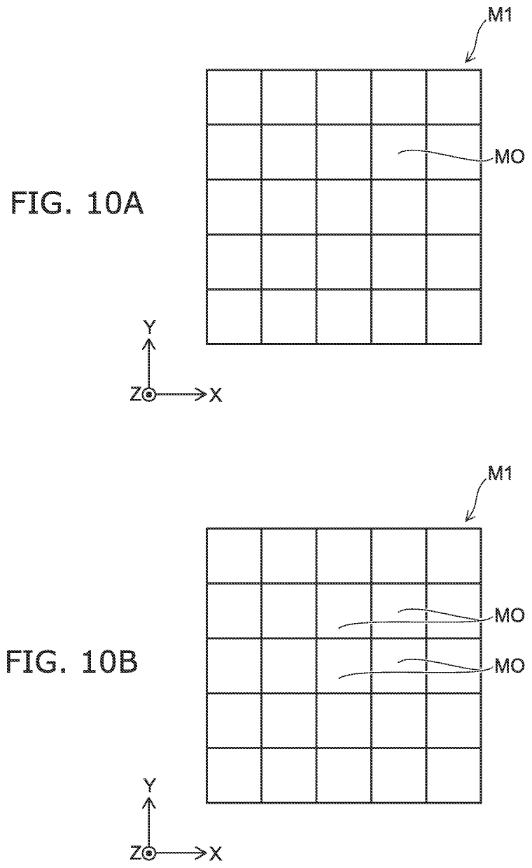

The three or more different coupling ratios are configured by three or more different materials of the second insulating film 40. This is achieved, for example, by the difference of the dose amount of the silicon ion into the second insulating film 40. For example, as shown in FIGS. 10A and 10B, a plurality of regions having different dose amount are formed in the second insulating film 40 by repetitive ion implantation using a mask while an opening area is changed.

For example, after the first ion implantation of the silicon using the mask M1 shown in FIG. 10A, the area of the opening portion MO of the mask M1 is spread, or the number of the opening portion MO is increased. And then the second ion implantation of the silicon is performed using the mask M1 shown in FIG. 10B.

The similar method described above is applicable to the second insulating film 40 having a material containing aluminum oxide.

As described above, according to the method for manufacturing the semiconductor memory device of the embodiment, the memory cells MC including the second insulating film 40 having different dielectric constant can be formed on one substrate 10 by only the additional ion implantation step with the mask. The memory cells MC including the second insulating film 40 having different dielectric constant have different coupling ratio CR and different characteristics. Therefore, according to the method for manufacturing the semiconductor memory device of the embodiment, the memory cells MC having different performance can be obtained on one substrate 10 without changing the size of the memory cells MC (height or width of the charge storage layer 30). According to the embodiment, the dielectric constant of the second insulating film 40 can be changed by the ion implantation or not. This makes it possible to obtain the memory cells MC having different performance on one substrate 10 at low cost.

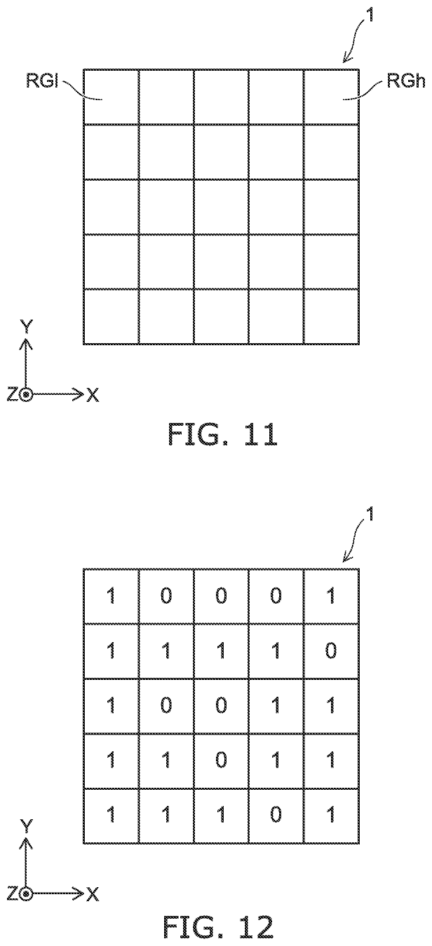

It is not limited to determining the coupling ratio for each memory cell MC in the memory cell array 1. As shown in FIG. 11, the coupling ratio may be determined for an area including the plurality of memory cells MC. Here, one memory cell array 1 including an area RGh having a high coupling ratio CR and an area RGI having a low coupling ratio CR is exemplified. The area RGh includes the plurality of first memory cells MCa, and does not include the second memory cell MCb. The area RGI includes the plurality of second memory cells MCb, and does not include the first memory cell MCa.

A plurality of memory cell arrays 1 may be formed in one chip, and the coupling ratio may be determined for the memory cell array 1. That is, the one-chip semiconductor memory device (memory chip) includes a first memory cell array including the plurality of first memory cells MCa and not including the second memory cell MCb, a second memory cell array including the plurality of second memory cells MCb and not including the first memory cell MCa.

As described above, the coupling ratio CR is determined according to the equation (1). As shown the following equation (2), the coupling ratio CR is a coefficient for calculating a voltage Vfg applied to the charge storage layer 30 from a voltage Vcg applied to the control gate electrode 50.

Vfg=CR·Vcg (2)

The voltage Vcg (control voltage) applied to the memory cell MC at writing and erasing is different depending on the coupling ratio CR of the memory cell MC. The memory cell having a higher coupling ratio CR may have a lower control voltage. The control voltage Vcgh of the second memory cell MCb having lower coupling ratio CR is higher than the control voltage Vcgl of the first memory cell MCa having higher coupling ratio CR.

If the same writing voltage Vcg is applied to the second memory cell MCb as the writing voltage Vcg of the first memory cell MCa, charge may not be injected to the charge storage layer 30 of the second memory cell MCb. That is, data may not be written to the second memory cell MCb. If the same erasing voltage Vcg is applied to the second memory cell MCb as the erasing voltage Vcg of the first memory cell MCa, charge may not be released from the charge storage layer 30 of the second memory cell MCb. That is, data may not be erased from the second memory cell MCb. According to the semiconductor device of the embodiment, the CR difference can determine 0/1 of the first memory cell MCa and the second memory cell MCb in one operating voltage by properly setting the voltage Vcg.

The area RGh including the first memory cell MCa can be used as a rewritable memory area and the area RGI including the second memory cell MCb can be used as a non-rewritable read only memory (ROM) area with the control voltage lower than the above Vcgh and being equal to the above Vcgl or higher than the above Vcgl. Before shipment of the product, data can be written to the second memory cell MCb with the control voltage being equal to the Vcgh or higher than the Vcgh. According to the semiconductor memory device of the embodiment, different two kinds of memory areas can be formed in one chip (on one substrate 10) without complex manufacturing process and changing the memory size.

Further, according to the semiconductor memory device of the embodiment, the data stored in the area RGI used as the ROM area can be rewritten only by changing the control voltage to the Vcgh. It is required to make a photomask when changing the stored data in the general ROM mask. In the embodiment, the stored data can be rewritten with the control voltage. This reduces costs of development and manufacturing.

Further, according to embodiment, writing/eracing characteristics can be changed for each memory cell MC. This allows the use as ROM storing data with inhibiting the writing to the predetermined area or entire area.

In that case, data may be programmed depending on the ion implantation or not with a mask M1 made according to the user's ROM code. That is, “0” or “1” is determined depending on the ion implantation or not. As shown in FIG. 12, the ion is implanted into the second memory cell MCb corresponding to the opening portion MO of the mask M1 and the data “1” is programmed in the second memory cell MCb. The ion is not implanted into the first memory cell MCa corresponding to the area other than the opening portion and the data “0” is programmed in the first memory cell MCa.

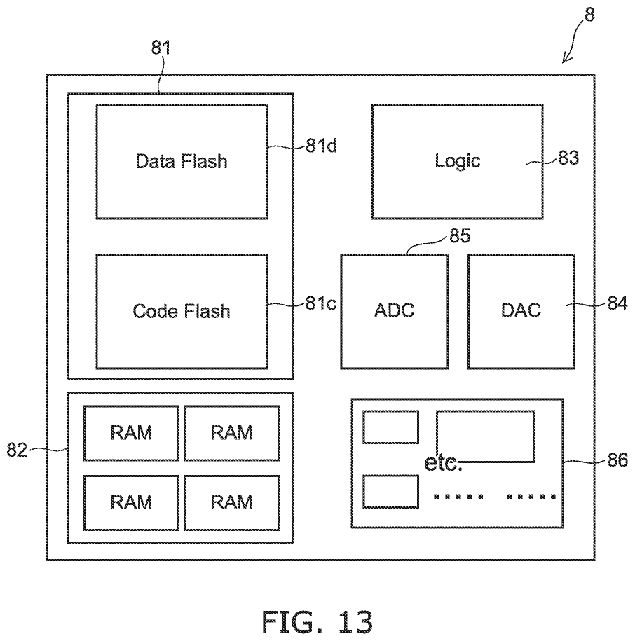

FIG. 13 is a schematic plan block diagram of a semiconductor device of another embodiment.

The semiconductor device is, for example, a micro controller unit (MCU) 8. The MCU 8 includes a memory portion 81, a memory portion 82, a logic circuit portion 83, a digital-analog converter (DAC) portion 84, an analog-digital converter (ADC) portion 85, and a peripheral circuit portion 86.

The memory portion 81, the memory portion 82, the logic circuit portion 83, the digital-analog converter (DAC) portion 84, the analog-digital converter (ADC) portion 85, and the peripheral circuit portion 86 are formed on the same substrate with one-chipped structure. Or the memory portion 81, the memory portion 82, the logic circuit portion 83, the digital-analog converter (DAC) portion 84, the analog-digital converter (ADC) portion 85, and the peripheral circuit portion 86 are formed as separate chips. These chips are mounted on an interposer with one-packaged structure.

The memory portion 81 corresponds to the above semiconductor memory device of the embodiment, and includes a data storage area 81d and a code storage area 81c.

The coupling ratio of the memory cell MC included in the data storage area 81d may be different from the coupling ratio of the memory cell MC included in the code storage area 81c. For example, the data storage area 81d may be made up of the first memory cell MCa, and the code storage area 81c may be made up of the second memory cell MCb.

In that case, in the same manner as the above embodiment, the dielectric constant of the second insulating film 40 may be change by the ion implantation in the manufacturing process of the memory portion 81. The coupling ratio of the memory cell MC included in the data storage area 81d may be different from the coupling ratio of the memory cell MC included in the code storage area 81c by the change of the dielectric constant of the second insulating film 40.

For example, a program executed by the logic circuit portion 83 is stored in the code storage area 81c. For example, a data controlled by the logic circuit portion 83 is stored in the data storage area 81d. The motor, the electronic device, the vehicle and others are controlled by the logic circuit portion 83.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming a first insulating film, a charge storage layer on the first insulating film, and a second insulating film on the charge storage layer above a substrate; and
changing a dielectric constant of an area of a part of the second insulating film.

2. The method according to claim 1, further comprising:
forming a control electrode on the second insulating film after the changing of the dielectric constant of the area of the part of the second insulating film.

3. The method according to claim 1, further comprising:
forming a control electrode on the second insulating film before the changing of the dielectric constant of the area of the part of the second insulating film, and after the forming of the second insulating film.

4. The method according to claim 1, wherein the changing the of the dielectric constant includes doping a first element into the area of the part of the second insulating film after the forming of the second insulating film.

5. The method according to claim 4, wherein
the second insulating film comprises hafnium oxide, and
the first element is silicon.

6. The method according to claim 4, wherein
the second insulating film comprises silicon oxynitride, and
the first element is aluminum.

7. The method according to claim 4, wherein the first element is implanted into the area of the part of the second insulating film by an ion implantation method.

8. A method for manufacturing a semiconductor device, comprising:
forming a first insulating film on a substrate;
forming a charge storage layer on the first insulating film;
forming a second insulating film on the charge storage layer; and
changing a dielectric constant of a region of the second insulating film by doping the region with a first dopant.

9. The method according to claim 8, further comprising:
forming a control electrode on the second insulating film.

10. The method according to claim 9, wherein the control electrode is formed on the second insulating film after the changing of the dielectric constant of the region of the second insulating film.

11. The method according to claim 9, wherein the control electrode is formed on the second insulating film before the changing of the dielectric constant of the region of the second insulating film.

12. The method according to claim 8, wherein the changing the of the dielectric constant of the region by doping includes an ion implantation process.

13. The method according to claim 8, wherein
the second insulating film comprises hafnium oxide, and
the first element is silicon.

14. The method according to claim 8, wherein
the second insulating film comprises silicon oxynitride, and
the first element is aluminum.

15. The method according to claim 8, wherein the substrate is a silicon substrate.
